(19) United States
(12) Patent Application Publication
(10) Pub. No.: US 2004/0229448 A1
(43) Pub. Date: Nov. 18, 2004

(54) Method for transforming an amorphous silicon layer into a polysilicon layer

(75) Inventors: Mao-Yi Chang, Taipei City (TW); Chieh-Chou Hsu, Kaohsiung City (TW); Ming-Yan Chen, Jubei City (TW); Ming-Jen Lu, Hsinchu City (TW)

Correspondence Address: BACON & THOMAS, PLLC, 625 SLATERS LANE, FOURTH FLOOR, ALEXANDRIA, VA, 22314

(73) Assignee: AU Optronics Corp., Hsinchu City (TW)

(21) Appl. No.: 10/635,489

(22) Filed: Aug. 7, 2003

(30) Foreign Application Priority Data
May 12, 2003 (TW) 92112804

(51) Int. Cl. H01L 21/265

(52) U.S. Cl. 438/518

(57) ABSTRACT

A method for transforming an amorphous silicon layer into a polysilicon layer is disclosed. The method includes following steps: providing an amorphous silicon substrate, doping the amorphous silicon substrate with an inert gas atom, and increasing the temperature of the surface of the amorphous silicon substrate by heat treatment or thermal process.

### BACKGROUND OF THE INVENTION

1. Field of the Invention

The present invention relates to a method for transforming an amorphous silicon (a-Si) layer into a polysilicon layer.

2. Description of Related Art

Amorphous silicon is currently the primary material for fabrication by semiconductor technology because of its advantages of simpler processing, suitability for mass production and lower production cost. However, a semiconductor element of amorphous silicon material has low electron mobility, and, as semiconductor elements become smaller and smaller in size, gradually cannot meet with the requirement for higher electron mobility. Hence, a new technique called “low temperature polysilicon” (LTPS) has been developed. The LTPS technique is widely used in manufacturing a liquid crystal display having thin film transistors (TFT-LCD).

The primary difference between the prior a-Si TFT-LCD and the LTPS TFT-LCD is that the transistors of the latter require an additional processing step of excimer laser annealing (ELA) to transform the a-Si film into a polysilicon thin film. The transformation improves the orientation of the silicon crystals of the TFT-LCD. Also, the electron mobility of the LTPS TFT-LCD is 100 times faster than that of the a-Si TFT-LCD, being increased up to 200 cm²/V-sec. Thus, the size of a TFT element can be reduced but possessing a longer and higher response time. As compared with the a-Si TFT-LCD, the size of the TFT element can be miniaturized at least one half, and the aperture ratio of the TFT element is increased. Also, the LTPS TFT-LCD has higher resolution and lower power consumption, as compared with the a-Si TFT-LCD of a same size. Moreover, because the electron mobility of the LTPS TFT-LCD is higher than that of the a-Si TFT-LCD, part of driver integrated circuit (IC) can be integrated into a glass substrate to reduce material cost. Also, damage to the products in modular assembly is prevented so as to increase yield and reduce production cost. Further, a simple adoption of a P-type circuit will reduce the quantity of photo masks used and the production cost, as compared with the conventional CMOS circuit. In addition, the integration of part of the driver IC reduces not only the weight of the IC but also the amount of other materials to be used in the following modular assembly. As a result, the weight of the LTPS TFT-LCD can be significantly reduced.

The a-Si precursor formed by chemical vapor deposition (CVD) has a narrow process window (10 to 20 mJ/cm²) for being subject to the ELA. The a-Si precursor is susceptible to laser beam instability. Any instability of the laser beam causes the polysilicon layer to be non-uniform, resulting in an adverse effect on yield of semiconductor elements.

Therefore, it is desirable to provide a method for transforming an amorphous silicon layer into a polysilicon layer to mitigate and/or obviate the aforementioned problems.

### SUMMARY OF THE INVENTION

It is a primary object of the present invention to provide a method for transforming an amorphous silicon layer into a polysilicon layer so that the sensitivity of the a-Si precursor to the laser beams stability is reduced and that the process window is widened.

It is another object of the present invention to provide a method for transforming an amorphous silicon layer into a polysilicon layer so as to reduce the energy density requirements for the excimer laser annealing and increase the total yield of production.

To attain the above-mentioned objects, a method for transforming an amorphous silicon layer into a polysilicon layer according to the present invention comprises: providing an amorphous silicon substrate, doping the amorphous silicon substrate with an inert gas atom, and heating of the surface of the amorphous silicon substrate by heat treatment or thermal process.

In essence, an inert gas is doped prior to transforming the a-Si layer into the polysilicon layer by the excimer laser annealing according to the method of the present invention. The doping of the inert gas such as helium, neon and argon into the a-Si precursor is to reduce the energy density (Eth) and the optimum energy density (Ec) in the transformation of the silicon crystals and further to widen the process window.

Other objects, advantages, and novel features of the invention will become more apparent from the following detailed description when taken in conjunction with the accompanying drawings.

### BRIEF DESCRIPTION OF THE DRAWINGS

FIG. 1 is a graph showing the relation between the electron mobility and the applied energy density according to an example of the present invention;

FIG. 2 is a graph showing the relation between the grain size and the energy density of an example of the present invention;

FIG. 3 is a graph showing the relation between the decreased value of the energy density and the doping energy according to an example of the present invention; and

FIG. 4 is a schematic view of a conventional excimer laser system.

### DETAILED DESCRIPTION OF THE PREFERRED EMBODIMENT

In the method for transforming an amorphous silicon layer into a polysilicon layer according to the present invention, the inert gas atom is preferably selected from a group consisting of nitrogen, helium, neon, argon, krypton, xenon and radon. Namely, the inert gas may be a single inert gas or a mixture of the inert gases. More preferably, the inert gas is argon. In the method of the present invention, the atom percentage of the inert gas atom in the a-Si substrate is not specifically defined. Preferably, the atom percentage of the inert gas atom in the a-Si substrate is in the range of from 1 to 0.001. In the present method, the doping of the inert gas atom is not specifically defined. Preferably, the inert gas atom is doped by plasma doping, chemical vapor deposition or dry etching. The functional element used in the method of present invention can be any conventional one. Preferably, the functional element serving as a switching device is a thin film transistor. The polysilicon substrate used in the method of the present invention can be any conventional one of plural purposes. Preferably, the polysilicon substrate is a panel for flat displays, and more preferably, a panel for liquid crystal displays. The process window of the excimer laser operated in the method of the present invention can be within the range of any conventional one, and preferably, the process window of the excimer laser is in the range of from 300 to 450 mJ/cm².

Example: The doping of argon on amorphous silicon substrate

In the present example, an amorphous silicon substrate is doped with argon before transforming into a polysilicon substrate by excimer laser annealing.

A top gate structure of an N-type and a P-type MOSFETs (Metal Oxide Silicon Field Effect Transistors) is formed on a glass substrate. An a-Si layer having a thickness of 2000 angstroms is deposited by plasma enhanced chemical vapor deposition (PECVD) at the temperature of 430° C. to serve as a buffer layer. Then, another a-Si layer having a thickness of 500 angstroms is deposited in preparation for the excimer laser annealing (ELA).

Before the ELA, the a-Si layer is dehydrogenated in a nitrogen flow at 480° C. for ten minutes to form an oxide. Argon atoms are doped (argon-implantation) using 95% overlapped scanning ratio by continuous laser pulses having a duration of 30 ns per pulse. A first photo mask is used to pattern the polysilicon layer, and also, a source region, a drain region and a lightly doped drain (LDD) region each having a thickness of 1 mm are formed by ion-implantation. A silicon dioxide (SiO₂) having a thickness of 1000 angstroms is deposited by PECVD at 430° C. so as to form a gate insulator. Subsequently, processing steps including a metal gate deposition, formation of patterns and deposition of an inner dielectric layer are completed. After etching away channel holes, a secondary metal layer of titanium (Ti)/aluminum (Al)/Ti is deposited and etched. A hydrogenation is processed at a high temperature. Finally, a capping layer of silicon nitride (SiNₓ) is formed.

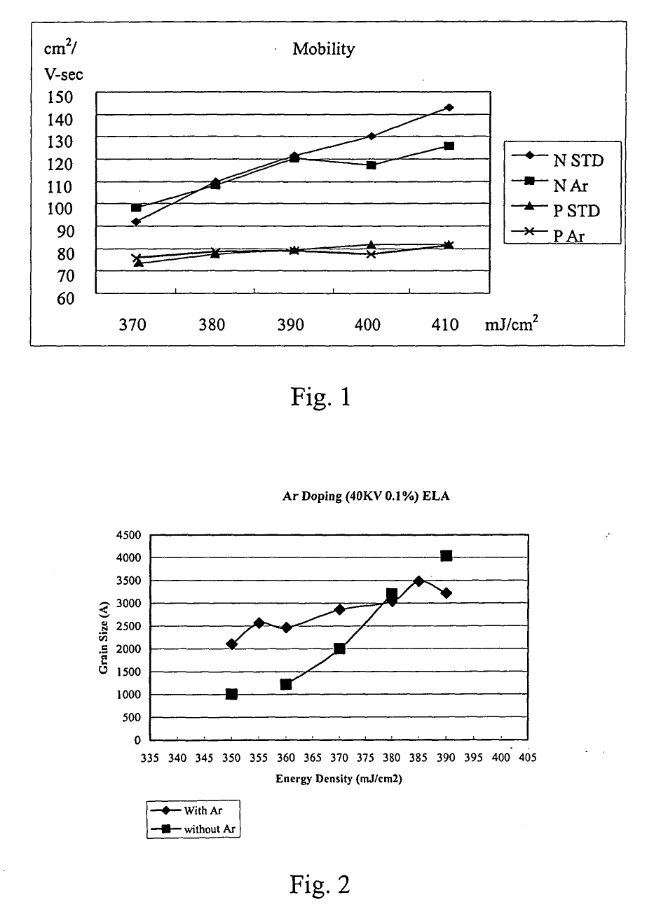

The results of the present example are shown in FIGS. 1, 2 and 3. FIG. 1 is a graph illustrating the relation between the electron mobility and the applied energy density of the present example. Four different experimental conditions, i.e., N-STD (standard NMOS), N-Ar (NMOS doped with argon atoms), P-STD (standard PMOS) and P-Ar (PMOS doped with argon atoms) are depicted in FIG. 1. It is inferable from FIG. 1 that the electron mobility of the Ar-doped polysilicon substrate is more stable than that of the undoped polysilicon substrate. Taking the NMOS element as an example, as mobility performance of from 120 to 130 cm²/V-sec is selected from the vertical axis of FIG. 1, the estimated slope of the curve (the electron mobility vs. the applied energy density) of the Ar-doped polysilicon substrate is smoother than that of the undoped polysilicon substrate within the performance range. Hence, the process window of the excimer laser energy density for annealing the Ar-doped polysilicon (390 to 410 mJ/cm²) is wider than that for annealing the undoped polysilicon (390 to 400 mJ/cm²). A wider process window means that more variations in laser energy are allowed. In other words, the electron mobility of the Ar-doped polysilicon substrate is less susceptible to the instability of the laser beam, or alternatively, the sensitivity of the electron mobility of the Ar-doped polysilicon substrate to the instability of the laser beam is reduced. Since the adverse effect caused by the instability of the laser beam on the uniformity has been reduced, yield of production shall be increased. On the other hand, the electron mobility of the Ar-doped polysilicon substrate is lower than that of the undoped polysilicon substrate. Even so, with reference to the NMOS element shown in FIG. 1, the electron mobility of the Ar-doped polysilicon is slightly lower than that of the undoped polysilicon. Taking the energy density of 410 mJ/cm² as an example, the difference in the electron mobility between the Ar-doped polysilicon and the undoped polysilicon is about 15%. Further, there is almost no difference in the electron mobility for the PMOS, regardless of the argon doping.

FIG. 2 shows the relation between the grain size and the energy density according to the present example. As shown, the process window for processing the Ar-doped polysilicon substrate is much wider than that for processing the undoped polysilicon substrate. Taking a grain size distributed within a size range of from 2500 to 3000 angstroms as an example, the process window of the laser scanning on the undoped polysilicon substrate is in the range of about 373 to about 378 mJ/cm² while the process window of the laser scanning on the Ar-doped polysilicon substrate is in the range of about 360 to about 380 mJ/cm². Hence, the allowed variations in the laser scanning energy have been increased four times after the argon doping. Accordingly, the present invention is capable of widening the process window of the excimer laser annealing, reducing occasions of error and increasing product yield.

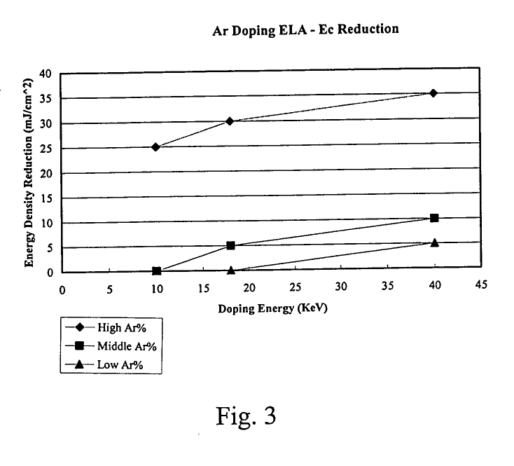

FIG. 3 shows the relation between the decreased value of the energy density and the doping energy according to the present example. As shown, the higher percentage of the argon doping, the greater the reduction of the energy density. It is inferable from FIG. 3 that the optimum energy density (Ec) for processing the Ar-doped polysilicon substrate is less than the laser energy used for the doping. The excess laser energy can be applied to broaden the width of the laser scanning so as to shorten the time required for scanning every substrate, increase yield and reduce fabrication costs.

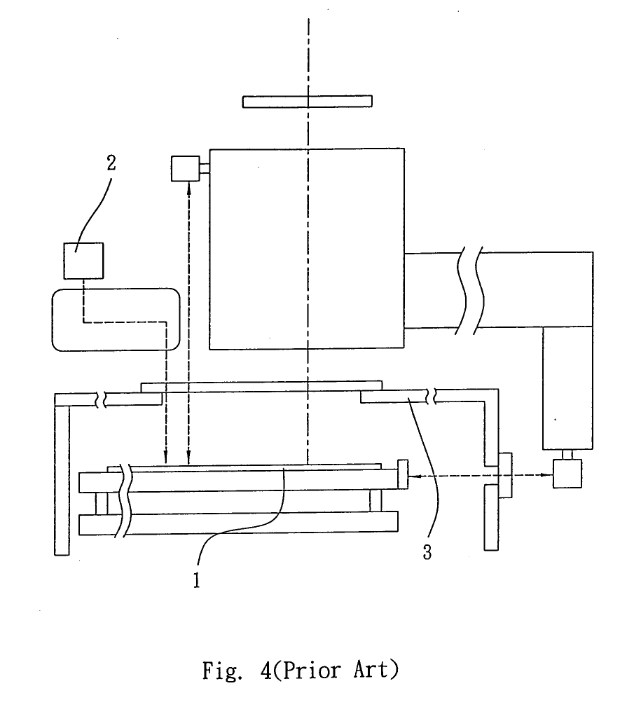

FIG. 4 schematically shows a conventional excimer laser system. The excimer laser system comprises an excimer laser irradiation element 2 and a support 3 for holding a substrate 1. The excimer laser irradiation element 2 is connected to a supporting arm (not shown). The surface of the substrate 1 is scanned in a predetermined manner to heat up the surface so as to finish annealing process and to transform the amorphous silicon into the polysilicon.

In conclusion, the introduction of the argon doping prior to annealing the traditional a-Si layer can not only widen the process window of the laser annealing but also reduce the Ec for the laser annealing. Also, the excess energy of the excimer laser apparatus can be used to broaden the width of the laser scanning, shorten the time for scanning every substrate and increase the efficiency of production lines.

Although the present invention has been explained in relation to its preferred embodiment, it is to be understood that many other possible modifications and variations can be made without departing from the spirit and scope of the invention as hereinafter claimed.

What is claimed is:

1. A method for transforming an amorphous silicon layer into a polysilicon layer, comprising:
providing an amorphous silicon substrate, and doping said amorphous silicon substrate with an inert gas atom; and
heating the surface of said amorphous silicon substrate by heat treatment or thermal process.

2. The method of claim 1, wherein said inert gas atom is selected from a group consisting of helium, neon, argon, krypton, xenon and radon.

3. The method of claim 2, wherein said inert gas atom is argon.

4. The method of claim 1, wherein the atom percentage of said inert gas atom in said amorphous silicon substrate is in the range of from 1 to 0.001.

5. The method of claim 1, wherein said inert gas atom is doped by plasma doping.

6. The method of claim 1, wherein said inert gas atom is doped by chemical vapor deposition.

7. The method of claim 1, wherein said inert gas atom is doped by dry etching.

8. The method of claim 1, wherein said polysilicon substrate is a panel of a liquid crystal display.

9. The method of claim 1, wherein said heat treatment is an excimer laser annealing.

10. The method of claim 9, wherein the process window of said excimer laser is in the range of from 300 to 450 mJ/cm².
